(19) United States
(12) Patent Application Publication
(10) Pub. No.: US 2021/0225054 A1
(43) Pub. Date: Jul. 22, 2021

(54) LAYOUT IMAGE ADJUSTMENT METHOD AND DEVICE, AND PLATFORM SYSTEM USING THE SAME

(71) Applicant: Chu-Hsin Chang, Hsinchu County (TW)

(72) Inventor: Chu-Hsin Chang, Hsinchu County (TW)

(21) Appl. No.: 17/069,593

(22) Filed: Oct. 13, 2020

(30) Foreign Application Priority Data
Jan. 17, 2020 (TW) 109101723

(51) Int. Cl. G06T 11/60; G06Q 10/02; G06Q 50/16; G06F 30/13

(52) U.S. Cl. CPC G06T 11/60; G06F 30/13; G06Q 50/163; G06Q 10/02

(57) ABSTRACT

A layout image adjustment method is illustrated, which has steps as follows: adjusting pattern dimensions of patterns in the layout image according to an effective region dimension; adjusting pattern positions of the patterns according to the effective region dimension; after the pattern positions are adjusted according to the effective region dimension, adjusting at least one pattern position of overlapped patterns to make the overlapped patterns non-overlapped if there are the overlapped patterns; and after the at least one pattern position of the overlapped patterns is adjusted, adjusting a layout image dimension of the layout image according to the effective region dimension if there is at least one pattern exceeds the effective region.

### TECHNICAL FIELD

The present disclosure relates to a layout image adjustment technology, and in particular, to a method and device for adjusting a layout image according to an effective region dimension, and a platform system using the method or device.

### BACKGROUND

Layout images are flat images, and each of them has a plurality of patterns therein, wherein the patterns can be used to present tables, chairs, sofas, machines, entrances, exits or other objects which can be disposed in a space. The layout images are usually seen in life. For example, when the customers want to eat in restaurants, the customers log in platform system via smart phones to select restaurants, and to refer layout images of specific floors of the restaurants for inspecting positions of the tables or chairs disposed in spaces of the specific floors of the restaurants, such that the customers can select their favored positions to book. For another example, when interior designers design interiors of houses, they provide the layout images to house holders, such that the house holders can inspect positions of objects disposed in the interiors.

However, different electronic devices have different dimensions of displays, and according to disposition and handheld manners of the electronic devices (for example, pads or smart phones can be disposed or handheld without rotations, or the pads or smart phones can be disposed or handheld with a rotation of 90 degrees), effective regions have different effective region dimensions for displaying the layout images. For the different effective region dimensions, if the layout images are not adjusted, it may cause inconvenience to users of the electronic devices for viewing the layout images, and the user experience may be poor. Though there are methods or devices to scale down the whole layout images according to the effective region dimensions, the patterns in the scaled down layout images may be too small, it still causes inconvenience to the users of the electronic devices for viewing the layout images, and the user experience is still poor.

### SUMMARY

An object of the present disclosure is to provide a layout image adjustment method which used to adjust a layout image comprising a plurality of patterns therein according to an effective region dimension of an effective region. The layout image adjustment method comprises steps of: adjusting pattern dimensions of the patterns in the layout image according to the effective region dimension; adjusting pattern positions of the patterns according to the effective region dimension; adjusting at least one pattern position of overlapped patterns to make the overlapped patterns non-overlapped if there are the overlapped patterns after the pattern positions are adjusted according to the effective region dimension; and adjusting a layout image dimension of the layout image according to the effective region dimension if there is at least one pattern exceeds the effective region after the at least one pattern position of the overlapped patterns is adjusted.

Another object of the present disclosure is to provide a platform system which comprises a platform server or a cloud computing service apparatus, at least one customer terminal device and at least one proprietor terminal device. The customer terminal device is communicatively connected to the platform server or the cloud computing service apparatus. The proprietor terminal device is communicatively connected to the platform server or the cloud computing service apparatus, and the platform server or the cloud computing service apparatus obtains a layout image comprising a plurality of patterns via the proprietor terminal device. At least one at least one of the platform server or the cloud computing service apparatus, the customer terminal device or the proprietor terminal device is used to execute the steps of the layout image adjustment method.

Another object of the present disclosure is to provide a layout image adjustment device which used to adjust a layout image comprising a plurality of patterns therein according to an effective region dimension of an effective region, and the layout image adjustment device comprises a pattern dimension adjustment module, a pattern position adjustment module and a layout image dimension adjustment module. The pattern dimension adjustment module is used to adjust pattern dimensions of the patterns in the layout image according to the effective region dimension. The pattern position adjustment module is connected to the pattern dimension adjustment module, used to adjust pattern positions of the patterns according to the effective region dimension, and used to adjust at least one pattern position of overlapped patterns to make the overlapped patterns non-overlapped if there are the overlapped patterns after the pattern positions are adjusted according to the effective region dimension. The layout image dimension adjustment module is connected to the pattern position adjustment module, and used to adjust a layout image dimension of the layout image according to the effective region dimension if there is at least one pattern exceeds the effective region after the at least one pattern position of the overlapped patterns is adjusted.

Optionally, the adjusted pattern dimension is not less than a minimum pattern dimension, a transformation curve between the effective region dimension and the pattern dimension is a linear curve, a step curve or an arbitrary monotonically increasing function curve, a transformation curve between the effective region dimension and the pattern position is a linear curve or an arbitrary monotonically increasing function curve, and a transformation curve between the effective region dimension and the layout image dimension is a linear curve or an arbitrary monotonically increasing function curve.

Optionally, the effective region dimension comprises a width and/or a length of the effective region, the pattern position comprises a vertical distance and/or a horizontal distance of the pattern is respect to a reference point, and the layout image dimension comprises a width and/or a length of the layout image.

Optionally, when adjusting the at least one pattern position of the overlapped patterns, one of the overlapped patterns is fixed and another one of the overlapped patterns is moved to make the overlapped patterns non-overlapped.

Optionally, the top and/or left one of the overlapped patterns is fixed, and the other one of the overlapped patterns is moved down and/or right.

Optionally, the pattern comprises auxiliary information.

Optionally, the auxiliary information comprises a table number, a maximum capacity and a minimum booking number of people.

Optionally, the platform system is a platform system which allows the restaurant proprietor to provide a restaurant space layout image to customers for booking, a platform system which allows an interior designer to provide an interior design layout image to a householder for referring, a platform system which allows an exhibition layout staff to provide an exhibition layout image to an exhibition holder for referring or a platform system which allows a wedding consultant to provide a wedding banquet layout image to a wedding couple for referring.

In short, compared to the prior art, by using the layout image adjustment method, device and the platform system of an embodiment of the present disclosure, when the users use different terminal devices to view the layout image, the poor user experiences can be avoided since the patterns in the adjusted layout image have proper sizes and pattern positions of the patterns are clear to be viewed.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a block diagram of a platform system according to an embodiment of the present disclosure.

FIG. 2 is a block diagram of a layout image adjustment device according to an embodiment of the present disclosure.

FIG. 3 is a flow chart of a layout image adjustment method according to an embodiment of the present disclosure.

FIG. 4A is a schematic diagram showing a transformation curve between an effective region dimension and a pattern dimension according to an embodiment of the present disclosure.

FIG. 4B is a schematic diagram showing another one transformation curve between an effective region dimension and a pattern dimension according to another one embodiment of the present disclosure.

FIG. 4C is a schematic diagram showing a transformation curve between an effective region dimension and a pattern position according to an embodiment of the present disclosure.

FIG. 4D is a schematic diagram showing a transformation curve between an effective region dimension and a layout image dimension according to an embodiment of the present disclosure.

FIG. 5 is a flow chart of a restaurant booking application using a platform system according to an embodiment of the present disclosure.

FIG. 6 is a schematic diagram of a layout image of a proprietor terminal device or a customer terminal device (or different customer terminal devices) according to an embodiment of the present disclosure.

FIG. 7A and FIG. 7B are schematic diagrams showing at least one of pattern positions of overlapped patterns is adjusted to make the overlapped pattern non-overlapped according to an embodiment of the present disclosure.

FIG. 8 is a schematic diagram showing at least one of pattern positions of overlapped patterns is adjusted to make the overlapped pattern non-overlapped according to another one embodiment of the present disclosure.

### DETAILED DESCRIPTION OF THE PREFERRED EMBODIMENTS

The present disclosure provides a technology for adjusting a layout image according to an effective region dimension, wherein the effective region dimension comprises at least one of a width and a length of an effective region which is used to display the adjusted layout image, and the present disclosure is not limited thereto. Briefly speaking, the layout image adjustment method and device adjust pattern dimensions and pattern positions of patterns in the layout image according to the effective region, wherein the pattern dimension comprises at least one of a width and a length of the pattern, and the present disclosure is not limited thereto. In an embodiment, the adjusted pattern is not less than a minimum pattern dimension. Next, at least one pattern position of the overlapped pattern is adjusted, and then the whole layout image is scaled down to make a layout image dimension match the effective region dimension if the layout image dimension is larger than the effective region dimension after the at least one pattern position of the overlapped pattern is adjusted, wherein the layout image dimension comprises at least one of a width and a length of the layout image, and the present disclosure is not limited thereto.

By using the above technology, since the pattern dimensions are adjusted according to the effective region dimension, such that the situation that the pattern is too small can be avoided. Further, by adjusting the at least one pattern position of the overlapped patterns and selectively scaling down the whole layout image, the situation that the patterns are overlapped and the adjusted layout image exceeds the effective region can be avoided, and the effective region is fully used to display the adjusted layout image. Even the customer users use different customer terminal devices having different effective regions to view the layout image, the poor user experiences can be avoided since the patterns in the adjusted layout image have proper sizes and pattern positions of the patterns are clear to be viewed. In other words, the layout image adjustment method and device according to embodiments of the present disclosure can enhance the user experiences and conveniences.

Further, the layout image adjustment method and device according to embodiments of the present disclosure can applied in platform systems of different fields and applications, for example, a platform system which allows the restaurant proprietor to provide a restaurant space layout image to customers for booking, a platform system which allows an interior designer to provide an interior design layout image to a householder for referring, a platform system which allows an exhibition layout staff to provide an exhibition layout image to an exhibition holder for referring and a platform system which allows a wedding consultant to provide a wedding banquet layout image to a wedding couple for referring. Accordingly, the layout image adjustment method and device of the present disclosure have the practical applications and high industrial usages.

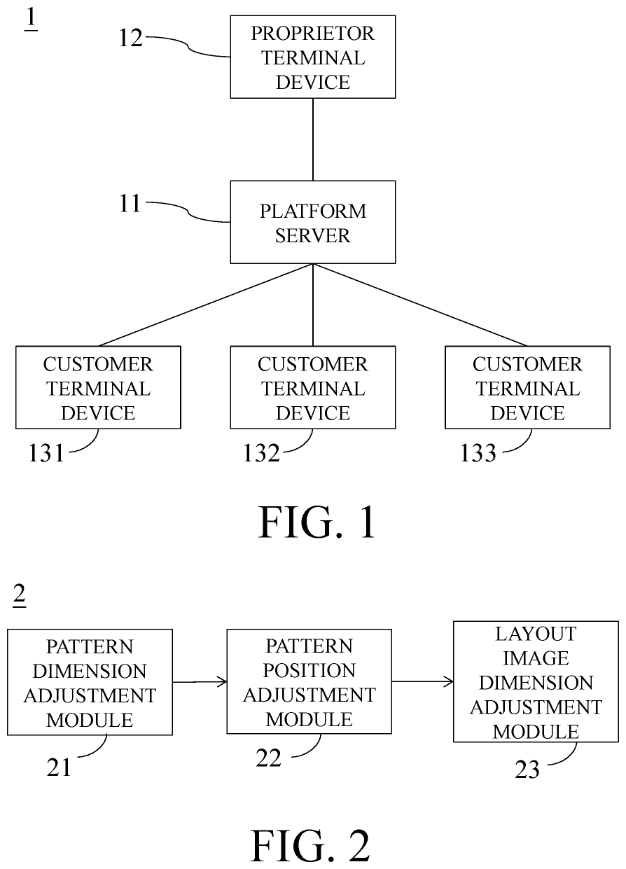

After illustrating the invention concepts of the present disclosure, please refer FIG. 1, and FIG. 1 is a block diagram of a platform system according to an embodiment of the present disclosure. The platform system 1 comprises a platform server 11, a proprietor terminal device 12 and a plurality of customer terminal devices 131-133, wherein the platform server 11 is communicatively connected to the proprietor terminal device 12 and the customer terminal devices 131-133. The platform server 11 can be replaced with a cloud computing service apparatus, and the embodiments of the present disclosure are illustrated with the examples of the platform server 11. The platform server 11 can have a layout image adjustment device for adjusting a layout image which is provided by the proprietor terminal device 12 and comprises patterns therein, wherein the customer terminal devices 131-133 may have different effective region dimensions, and the layout image adjustment device adjusts the layout image according to the effective region dimension, such that the adjusted layout images can be fully displayed within effective regions of the customer terminal devices 131-133, the patterns in the adjusted layout image are not too small and overlapped, and the customer users of the customer terminal devices 131-133 can clearly view the each pattern and each pattern position of the adjusted layout images.

It is noted that, though in the embodiment of FIG. 1, the platform server 11 is designed to be installed with the layout image adjustment device, the present disclosure is not limited thereto. In another one embodiment, the layout image adjustment device is installed in at least one the proprietor terminal device 12 and the customer terminal devices 131-133. Further, the proprietor terminal device 12 may not provide the layout image to the platform server 11, but the proprietor terminal device 12 links to the platform server 11 and operates the platform server 11 to generate the layout image, i.e. the platform system 1 utilizes architecture of Software as a Service (SAAS). The layout image adjustment device of the platform server 11 adjusts the layout image according to the effective region dimension of the proprietor terminal device 12, such that the proprietor user of the proprietor terminal device 12 can clearly view the each pattern and each pattern position of the adjusted layout image. In the preferred embodiment of the present disclosure, the platform server 11 is installed with the layout image adjustment device, and the platform system 1 utilizes the architecture of Software as a Service (SAAS).

Next, referring to FIG. 2, FIG. 2 is a block diagram of a layout image adjustment device according to an embodiment of the present disclosure. The layout image adjustment device 2 comprises a pattern dimension adjustment module 21, a pattern position adjustment module 22 and a layout image dimension adjustment module 23, wherein the pattern position adjustment module 22 is connected to the pattern dimension adjustment module 21, and the layout image dimension adjustment module 23 is connected to the pattern position adjustment module 22. The layout image adjustment device 2 can be implemented by hardware circuits (for example, a Field Programmable Gate Array (FPGA) chip complied via Verilog or VHDL or an Application-Specific Integrated Circuit (ASIC)) or software modules formed by executing codes (complied by C++, JAVA, JAVA script or Python) via a computing device (such as, a generic computer), and the present disclosure is not limited thereto.

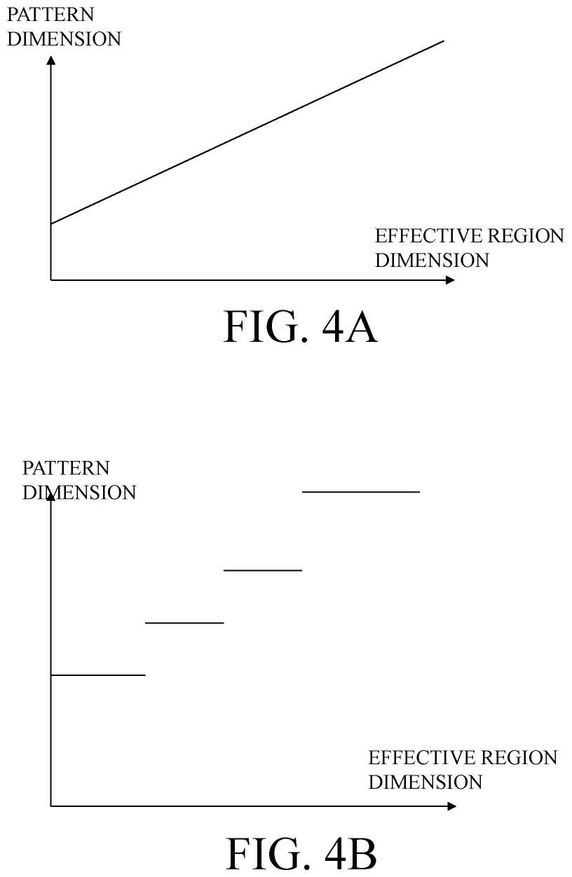

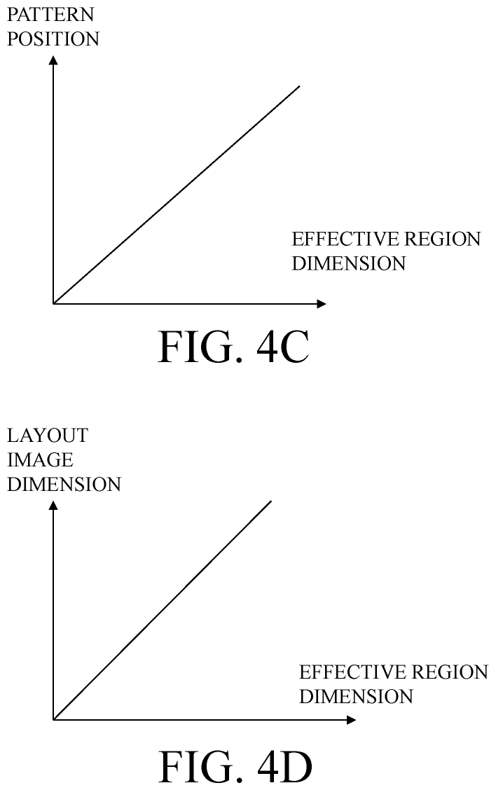

The pattern dimension adjustment module 21 acquires the effective region dimension of the proprietor terminal device or the customer terminal device, and adjusts the pattern dimensions according to the effective region dimension. For example, the effective region dimension comprises the width and/or length of the effective region, the pattern dimension comprises the width and/or length of the pattern, and the pattern dimension adjustment module 21 adjusts the widths and/or lengths of the patterns according to the width and/or length of the effective region, wherein the larger are the width and/or length of the effective region, the larger are the adjusted widths and/or lengths of the patterns, but the adjusted widths and/or lengths of the patterns are not less than a minimum width and/or a minimum length, so as to prevent the situation that the adjusted patterns are too small to be clearly viewed by the customer or proprietor user. Specifically, a transformation curve between the effective region dimension and the pattern dimension is a linear curve (as shown in FIG. 4A), a step curve (as shown in FIG. 4B) or an arbitrary monotonically increasing function curve, and the present disclosure is not limited thereto.

After the pattern dimensions are adjusted, the pattern position adjustment module 22 adjusts the pattern positions according to the effective region dimension. For example, the effective region dimension comprises the width and/or length of the effective region, the pattern position comprises a vertical distance and/or a horizontal distance from a reference point to the central point of the pattern, the pattern position adjustment module 22 adjusts the vertical distances and/or the horizontal distances from the reference point to the central points of the patterns according to the width and/or length of the effective region, wherein the larger are the width and/or length of the effective region, the larger are the adjusted vertical distances and/or the adjusted horizontal distances from the reference point to the central points of the patterns. Specifically, a transformation curve between the effective region dimension and the pattern position is a linear curve (as shown in FIG. 4C) or an arbitrary monotonically increasing function curve, and the present disclosure is not limited thereto. Moreover, the reference point is generally the top and left vertex point of the layout image.

After the pattern positions are adjusted, there are two or more than two adjusted patterns overlapped in the adjusted layout image, and thus the pattern position adjustment module 22 further adjust at least one of pattern positions of the overlapped patterns to make the overlapped patterns non-overlapped. For example, the top left, top or most left one of the overlapped patterns is fixed (i.e. the pattern position of the top left, top or most left one of the overlapped patterns are not adjusted), and at least another one of the overlapped patterns is moved downward and/or right (i.e. at least another one pattern position of the overlapped patterns is adjusted) until the overlapped patterns are adjusted to be non-overlapped. The above manner for adjusting the overlapped patterns is one implementation of the present disclosure, and details of the adjustment of the overlapped patterns are not used to limit the present disclosure. The pattern position adjustment module 22 adjusts pattern positions of all overlapped patterns in the layout image until the all overlapped patterns in the layout image are adjusted to be non-overlapped.

When the pattern position adjustment module 22 adjusts the pattern positions of the overlapped patterns, the adjusted pattern is allowed to exceed the effective region (i.e. the adjust pattern position or the adjusted pattern itself exceed the effective region), and thus the layout image dimension is updated (i.e. the layout image dimension is extended) to accommodate all adjusted patterns. Next, when the one or more adjusted patterns exceed the effective region, the layout image dimension adjustment module 23 adjusts the layout image dimension according to the effective region dimension. For example, the effective region dimension comprises the width and/or length of the effective region, the layout image dimension comprises the width and/or length of the layout image, and the layout image dimension adjustment module 23 adjusts the width and/or length of the layout image according to the width and/or length of the effective region which is used to display the adjusted layout image, wherein the larger are the width and/or length of the layout image, the larger are the width and/or length of the layout image. Specifically, a transformation curve between the effective region dimension and the layout image dimension is a linear curve (as shown in FIG. 4D) or an arbitrary monotonically increasing function curve, and the present disclosure is not limited thereto.

By using the layout image adjustment device 2, even the effective dimensions of the effective region associated with the customer terminal device(s) and the proprietor terminal device for displaying the adjusted layout images are different from each other, the patterns in the adjusted layout image are not too small and overlapped, and the patterns and the pattern positions can be clearly viewed by the users of the customer terminal device(s) and the proprietor terminal device. Moreover, the customer terminal device or the proprietor terminal device can be held or disposed vertically or horizontally (i.e. the two holding/disposing manners have a rotation angle of 90 degrees), and the layout image adjustment device 2 can generate two adjusted layout images corresponding to the two holding/disposing manners to the customer terminal device or the proprietor terminal device, such that even the user holds or disposes the customer terminal device or the proprietor terminal device vertically or horizontally, the patterns and the pattern position of the adjusted layout image can still be clearly viewed by the user.

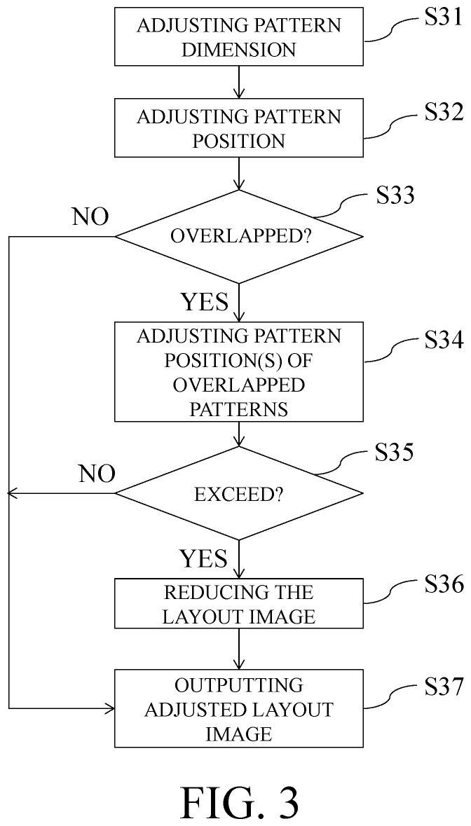

Next, referring to FIG. 3, FIG. 3 is a flow chart of a layout image adjustment method according to an embodiment of the present disclosure. The layout image adjustment method can be executed by the above layout image adjustment device, and the present disclosure is not limited thereto. The layout image adjustment method comprises steps S31 through S37, and the details are illustrated as follows. Firstly, at step S31, a pattern dimension of each pattern in the layout image is adjusted according to an effective region dimension of an effective region, wherein a transformation curve between the effective region dimension and the pattern dimension is a linear curve (as shown in FIG. 4A) or a step curve (as shown in FIG. 4B), and the present disclosure is not limited thereto. It is noted that, the adjusted pattern dimension is not less than a minimum pattern dimension, so as to further prevent the situation that the pattern in the adjusted layout image is too small to be clearly and easily viewed or recognized by the user.

Next, at step S32, a pattern position of each pattern in the layout image is adjusted according to the effective region dimension of the effective region, wherein a transformation curve between the effective region dimension and the pattern position is a linear curve (as shown in FIG. 4C), and the present disclosure is not limited thereto. After the pattern dimensions and pattern positions are adjusted, there may be overlapped patterns. Thus, at step S33, whether there are the overlapped patterns is determined. If there the overlapped patterns, step S34 is executed to adjust at least one pattern position of the overlapped patterns to make them non-overlapped. If there are no overlapped patterns, step S37 is executed to output the adjusted layout image.

At step S34, the at least one pattern position of the overlapped patterns is adjusted until there are no overlapped patterns, wherein the manner for adjusting the at least one pattern position of the overlapped patterns is to select one of the overlapped patterns to be fixed (for example, the top and left one), and move another one of the overlapped pattern downward and/or right until the overlapped patterns are adjusted to be non-overlapped. Step S34 is repeatedly executed until all patterns in the layout image are non-overlapped, and then step S35 is executed.

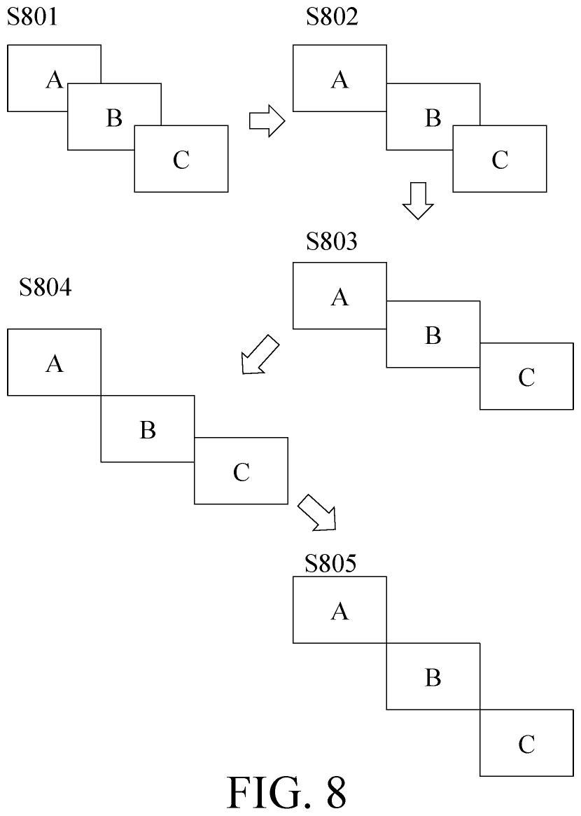

Referring to FIG. 3 and FIG., take FIG. 8 as an example to illustrate the adjustment of the at least one pattern position of the overlapped patterns. In FIG. 8, after the pattern positions are adjusted according to the effective region dimension, the patterns A, B and C are overlapped, as shown in state S801. Step S34 of FIG. 3 fixes the pattern A, and synchronously moves the patterns B and C right, so as to make the left edge of the pattern B and the right edge of the pattern A overlapped, as shown in state S802. Next, step S34 of FIG. 3 fixes the patterns A and B, and moves the pattern C right, so as to make the left edge of the pattern C and the right edge of the pattern B overlapped as shown in state S803. Then, step S34 of FIG. 3 fixes the pattern A, and synchronously moves the patterns B and C downward, so as to make the left edge of the pattern B and the right edge of the pattern A non-overlapped, as shown in state S804. Next, Step S34 of FIG. 3 fixes the patterns A and B, and moves the pattern C downward, so as to make the left edge of the pattern C and the right edge of the pattern B non-overlapped as shown in state S805. Since the patterns A, B and C are non-overlapped, step S34 of FIG. 4 is terminated, and then step S35 of FIG. 3 is executed.

Further refer to FIG. 3, after the pattern positions, the patterns may exceed the layout image dimension, and the layout image cannot be fully displayed on the effective region. Therefore, at step S35, whether one of the adjusted patterns exceeds the effective region is determined. If one of the adjusted patterns exceeds the effective region, the layout image dimension is updated, and then step S36 is executed to scale down the layout image. If no patterns exceed the effective region, step S37 is executed to output the adjusted layout image. At step S36, since the updated layout image dimension is larger than the effective region dimension, the layout image is scaled down according to the effective region dimension (i.e. the layout image dimension is adjusted), so as match the layout image dimension and the effective region dimension, wherein a transformation curve between the effective region dimension and the layout image dimension is a linear curve (as shown in FIG. 4D), and the present disclosure is not limited thereto. Next, at step S37, the adjusted layout image is output, wherein the layout image dimension matches the effective region dimension. The patterns in the adjusted layout image are not too small, and the patterns and the pattern positions can be clearly and easily viewed or recognized by the user.

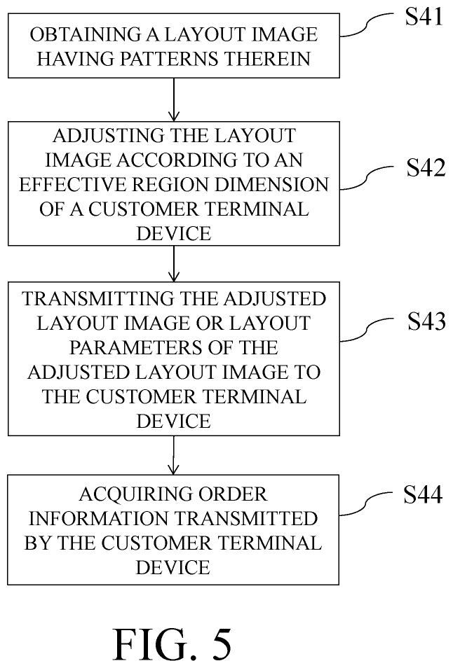

Next, referring to FIG. 5, FIG. 5 is a flow chart of a restaurant booking application using a platform system according to an embodiment of the present disclosure. Firstly, at step S51, the platform server obtains a layout image comprising a plurality of patterns. Specifically, the proprietor user of the proprietor terminal device (such as, a notebook, pad or smart phone) logs in the platform server to establish floors, generate the pattern of an entrance and the patterns of tables, and then to drag the patterns of the entrance and the tables to specific positions to generate allocation information, wherein not only a pattern dimension and a pattern shape of the pattern of the table can be set, but also auxiliary information of the pattern of the table can be input. The auxiliary information comprises a table number, a maximum capacity and a minimum booking number of people. The allocation information can be sent to the platform server, such that the platform server can obtain the layout image comprising the patterns via according to the allocation information. Further, the platform server can adjust the layout image according to the effective region dimension of the proprietor terminal device, and send the adjusted layout image to the proprietor terminal device which displays the adjusted layout image. The manner for adjusting the layout image is illustrated as above, and the redundant descriptions are omitted herein. The proprietor user of the proprietor terminal device can allocate reservation times and limitation numbers of people to each patterns of table, and can further provide menus, such that the customer user can make the reservation and complete the online booking.

When the customer user uses the customer terminal device (such as, a notebook, pad or smart phone) to log in the platform server for booking, steps S42 through S44 are executed. At step S42, the platform server can adjust the layout image according to the effective region dimension of the customer terminal device, and send the adjusted layout image to the customer terminal device which displays the adjusted layout image. Or alternatively, at step S42, the platform server transmits the layout parameters generated based on the adjusted layout image to the customer terminal device, and the customer terminal device can generate the adjusted image according to the received layout parameters of the adjusted layout image. The customer terminal device then displays the adjusted layout image on the effective region. By the way, the manner for adjusting the layout image is illustrated as above, and the redundant descriptions are omitted herein. It is noted that steps S42 and S43 are not used to limit the present disclosure, and in another embodiment, the platform server transmits the layout parameters of the original layout image to the customer terminal device, and the customer terminal device adjusts the layout image by the above manner for adjusting the layout image, and then obtains the layout parameters of the adjusted layout image. Next, at step S44, the platform server obtains the booking information transmitted by the customer terminal device.

The customer user can operate the customer terminal device to input a reservation date and time, a booking number of people and/or other keywords to the platform server, the platform server accordingly search restaurants which match the searching condition, and the platform server transmits the information of the searched restaurants to the customer terminal device. Next, the customer user selects one of the searched restaurants for making the reservation, and then the platform server transmits the adjusted layout image of the restaurant to the customer user device, such that the customer user can view and refer the layout of the restaurant. In another embodiment, the customer user may operate the customer user device to link to a webpage provided by the proprietor of the restaurant, and then, log in the platform server via the webpage, such that the platform server can transmit the adjusted layout image of the restaurant to the customer user device for booking. Or alternatively, the platform server transmits the original layout parameters of the layout image to the customer terminal device, and the customer terminal device itself adjusts the layout parameters to obtain the adjusted layout image. Next, the customer user can operate the customer terminal device to input information of the reservation data and time, a reservation table and the booking number of people to the platform server, so as to complete the booking.

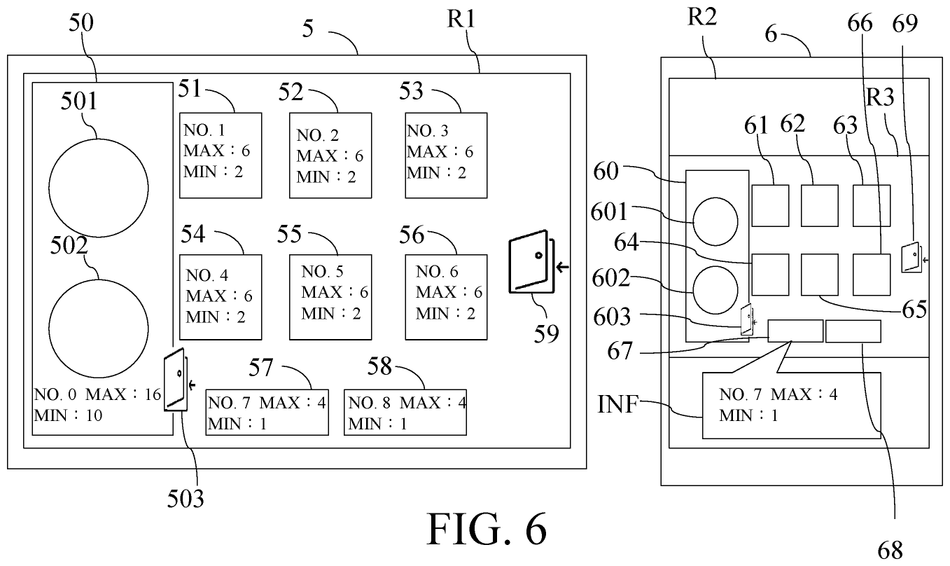

Next, refer to FIG. 6, and FIG. 6 is a schematic diagram of a layout image of a proprietor terminal device or a customer terminal device (or different customer terminal devices) according to an embodiment of the present disclosure. In FIG. 6, the proprietor terminal device 5 and the customer terminal device 6 respectively have the effective regions R1 and R3 for displaying the adjusted layout image. The effective region R1 is a display region of a display of the proprietor terminal device 5, and the customer terminal device 6 is a smart phone or pad, wherein when the customer terminal device 6 is disposed or held vertically, the effective region R3 for displaying the adjusted layout image is a part of a display region R2 of a display of the customer terminal device 6, and when the customer terminal device 6 is disposed or held horizontally, the effective region R3 for displaying the adjusted layout image is the display region R2 of the display of the customer terminal device 6.

In FIG. 6, the layout image displayed on the effective region R1 of the proprietor terminal device 5 comprises an entrance pattern 59, a room pattern 50 and table patterns 51-58, wherein the room pattern 50 further comprises two table patterns 501, 502 and a rom entrance pattern 503. Parts of the auxiliary information, such as, a table number, a maximum capacity and a minimum booking number of people can be displayed on the table patterns 51-58 and the room pattern 50. The effective region R3 of the customer terminal device 6 comprises an entrance pattern 69, a room pattern 60 and table patterns 61-68 which respectively corresponds to the entrance pattern 59, the room pattern 50 and table patterns 51-58, and the room pattern 60 comprises two table patterns 601, 602 and a rom entrance pattern 603 which respectively corresponds to the two table patterns 501, 502 and the rom entrance pattern 503.

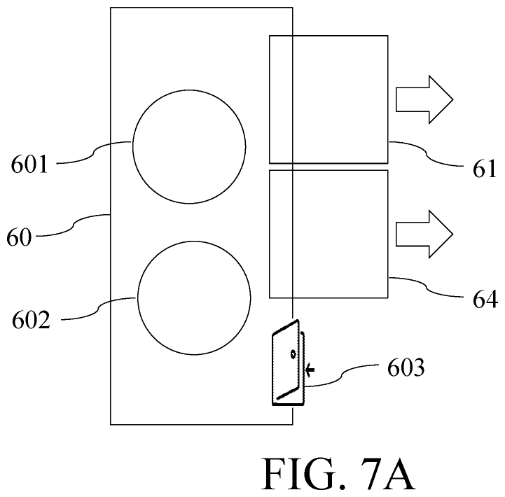

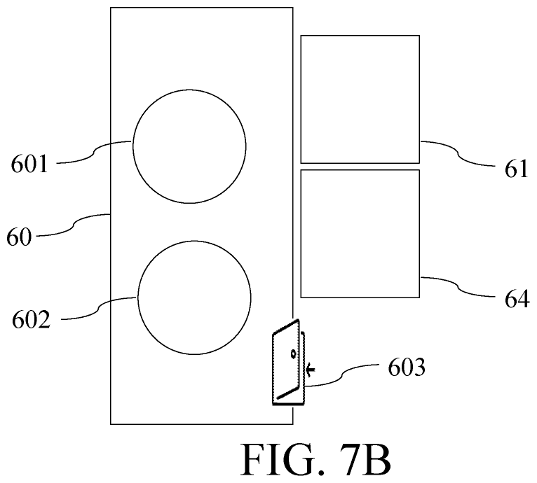

The entrance pattern 69, the room pattern 60, the table patterns 61-68, 601, 602 and the room entrance pattern 603 are obtained by scaling down the entrance pattern 59, the room pattern 50, the table patterns 51-58, 501, 502 and the room entrance pattern 603. However, as shown in FIG. 7A, the room pattern 60 and the table patterns 61, 64 are overlapped, thus, the room pattern 60 is fixed, and the table patterns 61 and 64 are moved right until they are non-overlapped as shown in FIG. 7B. In the embodiment, after the table patterns 61 and 64 are moved, they do not exceed the effective region R3, and the layout image dimension is not adjusted. However, if the moved able patterns 61 and 64 exceed the effective region R3, the layout image dimension should be adjusted to match the effective region dimension of the effective region R3. By the way, since pattern dimensions of the table patterns 61-68 and the room pattern 60 are smaller than those of the table patterns 51-58 and the room pattern 50, the auxiliary information of the table patterns 61-68 and the room pattern 60 are floatingly displayed on the information display block INF.

To sum up, a layout image adjustment method, device and a platform system using the same provided by embodiments of the present disclosure have the following benefit technical results. When the users use different terminal devices to view the layout image, the poor user experiences can be avoided since the patterns in the adjusted layout image have proper sizes and pattern positions of the patterns are clear to be viewed. In other words, the layout image adjustment method and device enhances the user experiences and conveniences. Furthermore, the layout image adjustment method and device can applied in platform systems of different fields and applications, such that the present disclosure has high industrial utilization value.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

1. A layout image adjustment method, used to adjust a layout image comprising a plurality of patterns therein according to an effective region dimension of an effective region, comprising:
adjusting pattern dimensions of the patterns in the layout image according to the effective region dimension;
adjusting pattern positions of the patterns according to the effective region dimension;
adjusting at least one pattern position of overlapped patterns to make the overlapped patterns non-overlapped if there are the overlapped patterns after the pattern positions are adjusted according to the effective region dimension; and
adjusting a layout image dimension of the layout image according to the effective region dimension if there is at least one pattern exceeds the effective region after the at least one pattern position of the overlapped patterns is adjusted.

2. The layout image adjustment method of claim 1, wherein the adjusted pattern dimension is not less than a minimum pattern dimension, a transformation curve between the effective region dimension and the pattern dimension is a linear curve, a step curve or an arbitrary monotonically increasing function curve, a transformation curve between the effective region dimension and the pattern position is a linear curve or an arbitrary monotonically increasing function curve, and a transformation curve between the effective region dimension and the layout image dimension is a linear curve or an arbitrary monotonically increasing function curve.

3. The layout image adjustment method of claim 1, wherein the effective region dimension comprises a width and/or a length of the effective region, the pattern position comprises a vertical distance and/or a horizontal distance of the pattern is respect to a reference point, and the layout image dimension comprises a width and/or a length of the layout image.

4. The layout image adjustment method of claim 1, wherein when adjusting the at least one pattern position of the overlapped patterns, one of the overlapped patterns is fixed and another one of the overlapped patterns is moved to make the overlapped patterns non-overlapped.

5. The layout image adjustment method of claim 4, wherein the top and/or left one of the overlapped patterns is fixed, and the other one of the overlapped patterns is moved down and/or right.

6. The layout image adjustment method of claim 1, wherein the pattern comprises auxiliary information.

7. The layout image adjustment method of claim 6, wherein the auxiliary information comprises a table number, a maximum capacity and a minimum booking number of people.

8. A platform system, comprising:
a platform server or a cloud computing service apparatus;
at least one customer terminal device, communicatively connected to the platform server or the cloud computing service apparatus; and
at least one proprietor terminal device, communicatively connected to the platform server or the cloud computing service apparatus, and the platform server or the cloud computing service apparatus obtains a layout image comprising a plurality of patterns via the proprietor terminal device;
wherein at least one of the platform server or the cloud computing service apparatus, the customer terminal device or the proprietor terminal device is used to:
adjust pattern positions of the patterns according to the effective region dimension;
adjust at least one pattern position of overlapped patterns to make the overlapped patterns non-overlapped if there are the overlapped patterns after the pattern positions are adjusted according to the effective region dimension; and
adjust a layout image dimension of the layout image according to the effective region dimension if there is at least one pattern exceeds the effective region after the at least one pattern position of the overlapped patterns is adjusted.

9. The platform system of claim 8, wherein the platform system is a platform system which allows the restaurant proprietor to provide a restaurant space layout image to customers for booking, a platform system which allows an interior designer to provide an interior design layout image to a householder for referring, a platform system which allows an exhibition layout staff to provide an exhibition layout image to an exhibition holder for referring or a platform system which allows a wedding consultant to provide a wedding banquet layout image to a wedding couple for referring.

10. The platform system of claim 8, wherein the adjusted pattern dimension is not less than a minimum pattern dimension, a transformation curve between the effective region dimension and the pattern dimension is a linear curve, a step curve or an arbitrary monotonically increasing function curve, a transformation curve between the effective region dimension and the pattern position is a linear curve or an arbitrary monotonically increasing function curve, and a transformation curve between the effective region dimension and the layout image dimension is a linear curve or an arbitrary monotonically increasing function curve.

11. The platform system of claim 8, wherein the effective region dimension comprises a width and/or a length of the effective region, the pattern position comprises a vertical distance and/or a horizontal distance of the pattern is respect to a reference point, and the layout image dimension comprises a width and/or a length of the layout image.

12. The platform system of claim 8, when adjusting the at least one pattern position of the overlapped patterns, a top and/or left one of the overlapped patterns is fixed, and another one of the overlapped patterns is moved down and/or right.

13. The platform system of claim 8, wherein the pattern comprises auxiliary information, and the pattern comprises auxiliary information comprises a table number, a maximum capacity and a minimum booking number of people.

14. A layout image adjustment device, used to adjust a layout image comprising a plurality of patterns therein according to an effective region dimension of an effective region, comprising:
a pattern dimension adjustment module, for adjusting pattern dimensions of the patterns in the layout image according to the effective region dimension;
a pattern position adjustment module, connected to the pattern dimension adjustment module, for adjusting pattern positions of the patterns according to the effective region dimension, and adjusting at least one pattern position of overlapped patterns to make the overlapped patterns non-overlapped if there are the overlapped patterns after the pattern positions are adjusted according to the effective region dimension; and
a layout image dimension adjustment module, connected to the pattern position adjustment module, for adjusting a layout image dimension of the layout image according to the effective region dimension if there is at least one pattern exceeds the effective region after the at least one pattern position of the overlapped patterns is adjusted.

15. The layout image adjustment device of claim 14, wherein the adjusted pattern dimension is not less than a minimum pattern dimension, a transformation curve between the effective region dimension and the pattern dimension is a linear curve, a step curve or an arbitrary monotonically increasing function curve, a transformation curve between the effective region dimension and the pattern position is a linear curve or an arbitrary monotonically increasing function curve, and a transformation curve between the effective region dimension and the layout image dimension is a linear curve or an arbitrary monotonically increasing function curve.

16. The layout image adjustment device of claim 14, wherein the effective region dimension comprises a width and/or a length of the effective region, the pattern position comprises a vertical distance and/or a horizontal distance of the pattern is respect to a reference point, and the layout image dimension comprises a width and/or a length of the layout image.

17. The layout image adjustment device of claim 14, wherein when adjusting the at least one pattern position of the overlapped patterns, one of the overlapped patterns is fixed and another one of the overlapped patterns is moved to make the overlapped patterns non-overlapped.

18. The layout image adjustment device of claim 17, wherein the top and/or left one of the overlapped patterns is fixed, and the other one of the overlapped patterns is moved down and/or right.

19. The layout image adjustment device of claim 14, wherein the pattern comprises auxiliary information.

20. The layout image adjustment device of claim 19, wherein the pattern comprises auxiliary information comprises a table number, a maximum capacity and a minimum booking number of people.
